(19) United States
(12) Patent Application Publication
(10) Pub. No.: US 2007/0004327 A1
(43) Pub. Date: Jan. 4, 2007

(54) Heat dissipation system and anti-backflow device

(75) Inventors: Peng-Chu Tao, Taoyuan Hsien (TW); Te-Tsai Chuang, Taoyuan Hsien (TW); Wen-Shi Huang, Taoyuan Hsien (TW)

Correspondence Address: BIRCH STEWART KOLASCH & BIRCH, PO BOX 747, FALLS CHURCH, VA, 22040-0747, US

(73) Assignee: DELTA ELECTRONICS, INC.

(21) Appl. No.: 11/447,080

(22) Filed: Jun. 6, 2006

(30) Foreign Application Priority Data
Jun. 30, 2005 (TW) 094211016

(51) Int. Cl. H05K 5/00

(52) U.S. Cl. 454/184

(57) ABSTRACT

An anti-backflow device includes a case and a plurality of flappers. The case has at least one opening and a plurality of combining portion. The combining portions are disposed in two opposite sides of the opening. The combining portions and the case are integrally formed. The flappers are disposed in the opening in sequence. Each flapper has a first connecting portion and a second connecting portion, each of which pivots on one of the combining portions.

### BACKGROUND OF THE INVENTION

1. Field of Invention

The invention relates to a heat dissipation system and an anti-backflow device thereof.

2. Related Art

With the progress in technology, the performance of electronic products becomes much better. However, if the heat generated during the operation of the electronic products is not properly removed in time, the efficiency of the electronic products would decrease and they may even be burnt out. To remove the generated heat, the heat dissipation system has become one of the essential components in the present electronic products.

Please refer to FIG. 1 and FIG. 2, which show the exploded and schematic views of a conventional heat dissipation system 1. The heat dissipation system 1 includes a case 11, a plurality of flappers 12, a plurality of fans 13 and two fastening frames 14. In this case, the case 11 includes a lower housing 111, which has a plurality of inlets 1111, and an upper housing 112. The fans 13 are located corresponding to the inlets 1111, respectively. The assembling procedure of the conventional heat dissipation system 1 includes the steps as following. First, the flappers 12 are arranged in parallel and pivoted on the fastening frames 14. Next, the lower housing 111 and the upper housing 112 are combined to form an opening, and then the fastening frames 14 are fixed in the opening.

However, in the above mentioned assembling procedure, the fastening frames 14 may be deformed if the mechanical strength thereof is unreliable. Thus, the heat dissipation system 1 can not be assembled easily, and the assembling steps become more complex. This is inefficient for the present industry requirements.

It is therefore an important subject of the invention to provide a heat dissipation system that can reduce the deformation of components and simplify the assembling steps for increasing the manufacturing speed.

### SUMMARY OF THE INVENTION

In view of the foregoing, the invention is to provide a heat dissipation system and an anti-backflow device thereof, which have a plurality of flappers pivoted on the case.

To achieve the above, an anti-backflow device of the invention includes a case and a plurality of flappers. In the invention, the case has at least one opening and a plurality of combining portions, which are located at two opposite sides of the opening. The combining portions and the casing are integrally formed. The flappers are arranged in the opening in sequence, and each flapper has a first connecting portion and a second connecting portion. The first connecting portion and the second connecting portion are respectively pivoted on one of the combining portions.

To achieve the above, a heat dissipation system of the invention includes a case, a plurality of flappers and at least one fan. In the invention, the case has at least one opening, a containing space, and a plurality of combining portions located at two opposite sides of the opening. The combining portions and the casing are integrally formed. The flappers are arranged in the opening in sequence, and each flapper has a first connecting portion and a second connecting portion. The first connecting portion and the second connecting portion are respectively pivoted on one of the combining portions. The fan is located in the containing space.

As mentioned above, the heat dissipation system and the anti-backflow device thereof have the flappers, which are directly pivoted on the opening of the case. This structure can provide good mechanical strength for preventing the deformation. Accordingly, the assembling procedure can be simplified so as to reduce the production cost.

### BRIEF DESCRIPTION OF THE DRAWINGS

The invention will become more fully understood from the detailed description given herein below illustration only, and thus is not limitative of the present invention, and wherein:

FIG. 1 is an exploded view of the conventional heat dissipation system;

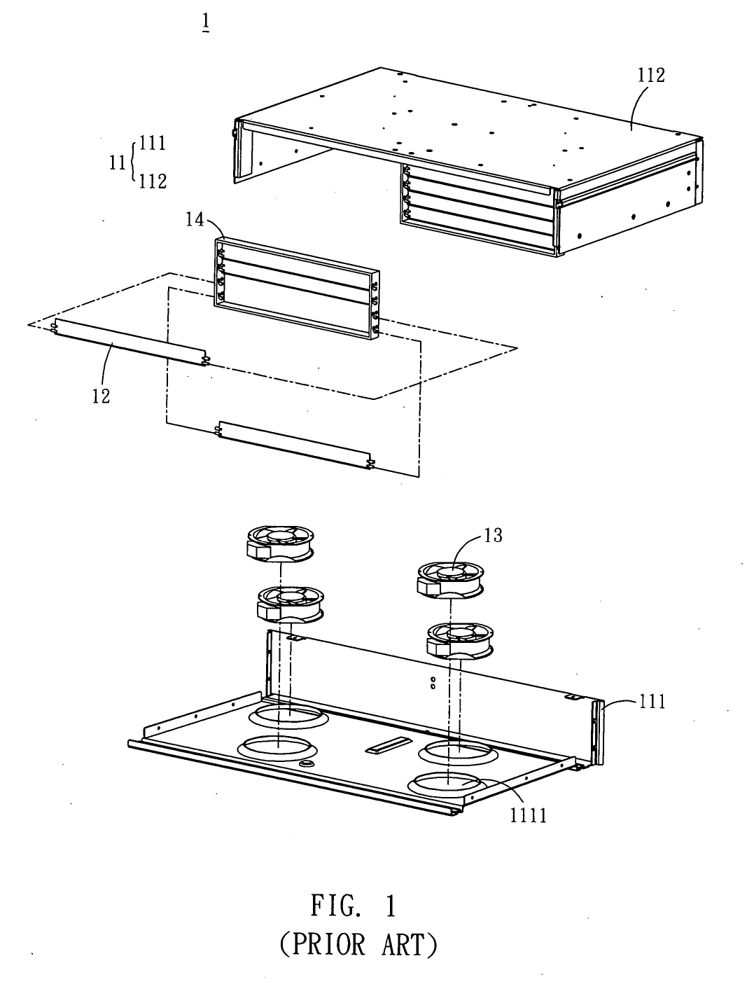

FIG. 2 is a schematic view of the conventional heat dissipation system;

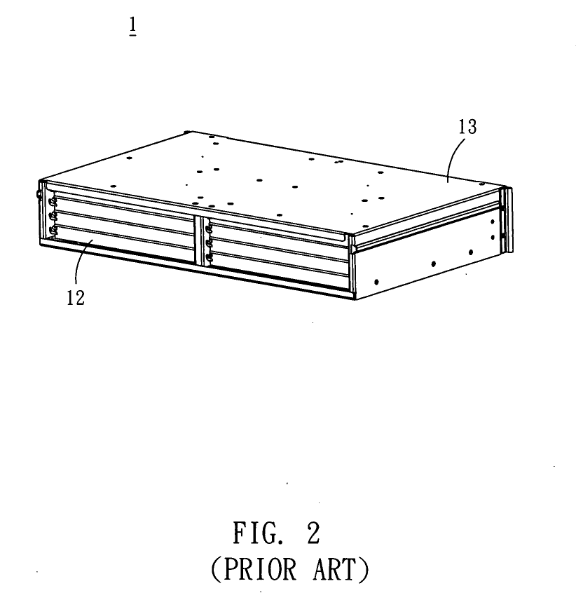

FIG. 3 is an exploded view of an anti-backflow device according to a preferred embodiment of the invention;

FIG. 4 is a schematic view of the anti-backflow device according to the preferred embodiment of the invention; and

FIG. 5 is a partial diagrammatic view of a heat dissipation system according to the preferred embodiment of the invention.

### DETAILED DESCRIPTION OF THE INVENTION

The present invention will be apparent from the following detailed description, which proceeds with reference to the accompanying drawings, wherein the same references relate to the same elements.

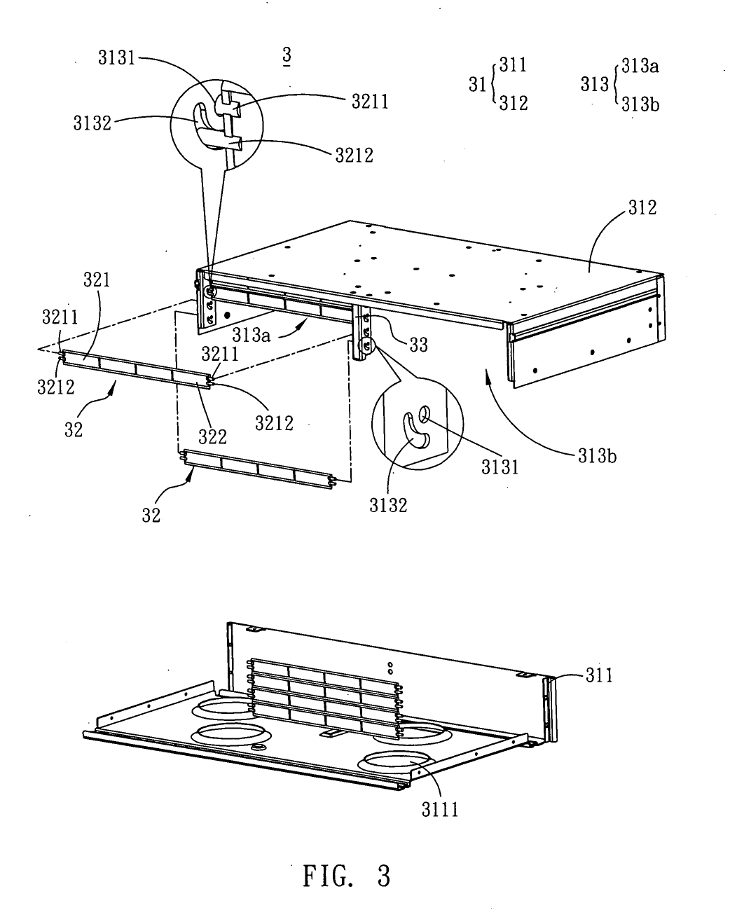

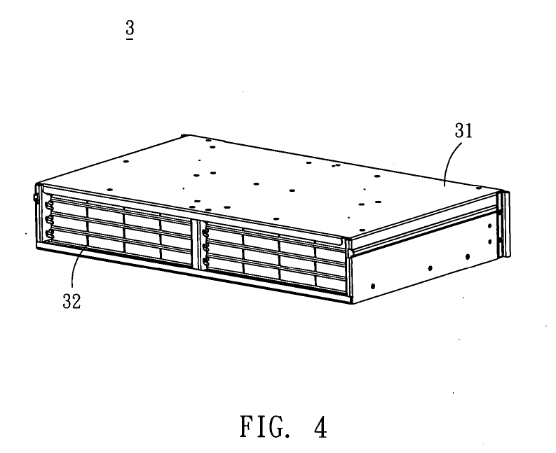

Please refer to FIG. 3 and FIG. 4, which show the exploded and schematic views of an anti-backflow device 3 according to a preferred embodiment of the invention. The anti-backflow device 3 includes a case 31, a plurality of flappers 32 and a partition 33.

In the embodiment, the case 31 includes a first housing 311 and a second housing 312. The first housing 311 has a plurality of inlets 3111. In this case, the first housing 311 and the second housing 312 are assembled by way of welding, riveting, screwing, adhering, wedging, clipping engaging, or the likes. Alternatively, the case 31 can be integrally formed. Accordingly, the case 31 can provide an opening 313 and a containing space constructed by the assemblage of the housings 311 and 312. The partition 33 is disposed between the housings 311 and 312 to divide the opening 313 into sub openings 313a and 313b. Besides, the partition 33 has a plurality of combining portions, such as the connecting holes 3131 in this embodiment, located at two sides of the partition 33.

Furthermore, there are plural combining portions, such as the connecting holes 3131 in this embodiment, located at two opposite sides of the sub openings 313a and 313b, and the case 31 and the combining portions are integrally formed. Besides, there is a corresponding sliding hole 3132 disposed adjacent to each connecting hole 3131. In the present embodiment, the sliding hole 3132 has a curved shape.

In the embodiment shown in FIG. 3, each flapper 32 has a first connecting portion 321 and a second connecting portion 322, which are located at two ends of the flapper 32. Each of the first connecting portion 321 and the second connecting portion 322 has a connecting shaft 3211 and a sliding pillar 3212.

The flappers 32 are arranged in the sub opening 313a or 313b in sequence. The connecting shafts 3211 are respectively pivoted on the connecting holes 3131, and the sliding pillars 3212 are respectively pivoted on and inserted into the sliding holes 3132. In the embodiment shown in FIG. 3, the distance between two adjacent connecting holes 3131 is substantially equal to the width of each flapper 32. Therefore, the flappers 32 can tightly arranged in the sub opening 313a or 313b for covering it. Of course, in another embodiment, the distance between two adjacent connecting holes 3131 may be substantially smaller than the width of each flapper 32, so that the flappers 32 are partially stacked on each other and thus cover the sub opening 313a or 313b.

In this case, the flapper 32 utilizes its sliding pillars 3212 to pivot on the sliding holes 3132. Thus, when the air is blown from the interior of the case 31 to the exterior, the flapper 32 is pushed by the air and the pillars 3212 slid along the connecting holes 3132. Then, the pillars 3212 are stopped when they slid to the ends of the connecting holes 3132. In other words, the ends of the sliding holes 3132 are for blocking the flapper 32 and thus restricting the open angle and direction of the flapper 32. To be noted, the curved shape of the sliding hole 3132 can be designed according to the desired open angle and direction of the flapper 32.

Of course, the opening 313 may have a plurality of protrusions (not shown) disposed at two sides of the opening 313. The protrusions are used as the blockers for blocking the flapper 32 and thus restricting the open angle and direction of the flapper 32. For example, if the protrusions are located at the two sides of the opening 313 and close to the interior of the case 31, the flapper 32 can be blocked from being opened toward the interior of the case 31. Accordingly, the external air can be prevented from being blown into the case 31.

The assembling procedure of the anti-backflow device 3 includes the following steps. First, the first housing 311, the second housing 312 and the partition 33 are combined to form the sub openings 313a and 313b. Then, the flappers 32 are installed in the sub openings 313a and 313b for finishing the assembling procedure. Since the first housing 311 and the second housing 312 have good mechanical strength, the deformations of the conventional art would not happen. Besides, the components of the invention are simplified, so that the anti-backflow device 3 of the invention is easily assembled.

In still another embodiment not shown in the figure, the first connecting portion 321 of the flapper 32 has the connecting shaft 3211 and the sliding pillar 3212, while the second connecting portion 322 has the connecting shaft 3211 only. This configuration can also achieve the above-mentioned effect.

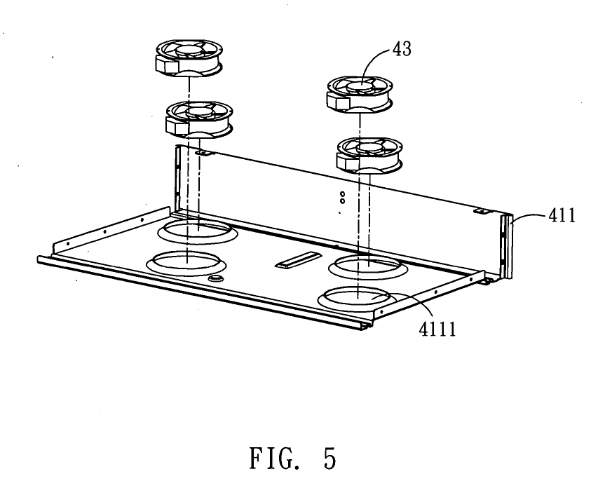

Please refer to FIG. 5, which shows a partial diagrammatic view of a heat dissipation system according to another preferred embodiment of the invention. The heat dissipation system includes a case composed of a first housing 411 and a second housing, a plurality of flappers and a plurality of fans 43. In this case, the case and flappers of the present embodiment are the same as the previously described case 31 and flappers 32, so the detailed descriptions are omitted for concise purpose. The fans 43 are located in the containing space of the case and opposite to the inlets 4111 of the first housing 411. The heat dissipation system is obtained by combining the anti-backflow device 3 and the fans 43.

In summary, the heat dissipation system and the anti-backflow device thereof have the flappers, which are directly disposed on the opening of the case. This structure can provide good mechanical strength for preventing the deformation. Moreover, the components of the invention are simplified. Compared with the conventional heat dissipation system, the system of the invention has the advantages of hard to be deformed and reduced components. Accordingly, the assembling procedure can be simplified so as to reduce the production cost.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. An anti-backflow device, comprising:
a case having at least one opening and a plurality of combining portions located at two opposite sides of the opening, wherein the combining portions and the casing are integrally formed; and
a plurality of flappers arranged in the opening, wherein each of the flappers has a first connecting portion and a second connecting portion, and each of the first connecting portion and the second connecting portion pivot on the combining portions, respectively.

2. The anti-backflow device of claim 1, wherein a partition is installed in the opening to divide the opening into two sub openings, the partition has a plurality of combining portions located at two sides of the partition, and the first connecting portion and the second connecting portion of each of the flappers pivot on the combining portions of the partition, respectively.

3. The anti-backflow device of claim 1, wherein the case further comprises a first housing and a second housing, and the first and second housings are assembled to form the opening.

4. The anti-backflow device of claim 3, wherein the first and second housings are assembled by way of welding, riveting, screwing, adhering, wedging, clipping or engaging.

5. The anti-backflow device of claim 1, wherein the combining portion is a connecting hole, and each of the first connecting portion and the second connecting portion has a connecting shaft pivoting on and inserted in the connecting hole.

6. The anti-backflow device of claim 5, wherein the opening further has at least two sliding holes located at two sides of the opening respectively, and each of the first connecting portion and the second connecting portion has a sliding pillar disposed in the sliding hole for the flapper to slide along the sliding holes.

7. The anti-backflow device of claim 6, wherein the sliding hole has a curved shape.

8. The anti-backflow device of claim 1, further comprising a plurality of blockers disposed at two sides of the opening for blocking the flapper from being opened toward the interior of the case.

9. The anti-backflow device of claim 1, wherein any two adjacent flappers have an interval substantially equal to the width of the flapper.

10. The anti-backflow device of claim 1, wherein any two adjacent flappers have an interval substantially smaller than the width of the flapper so that the flappers are partially stacked on each other.

11. A heat dissipation system, comprising:
a case having at least one opening, a containing space, and a plurality of combining portions located at two opposite sides of the opening, wherein the combining portions and the casing are integrally formed;
a plurality of flappers arranged in the opening, wherein each of the flappers has a first connecting portion and a second connecting portion, and the first connecting portion and the second connecting portion pivot on the combining portions, respectively; and
at least one fan located in the containing space.

12. The heat dissipation system of claim 11, wherein a partition is installed in the opening to divide the opening into two sub openings, the partition has a plurality of combining portions located at two sides of the partition, and the first connecting portion and the second connecting portion of each of the flappers pivot on the combining portions of the partition, respectively.

13. The heat dissipation system of claim 11, wherein the case further comprises a first housing and a second housing, and the first and second housings are assembled to form the opening.

14. The heat dissipation system of claim 13, wherein the first and second housings are assembled by way of welding, riveting, screwing, adhering, wedging, clipping or engaging.

15. The heat dissipation system of claim 11, wherein the combining portion is a connecting hole, and each of the first connecting portion and the second connecting portion has a connecting shaft pivoting on and inserted in the connecting hole.

16. The heat dissipation system of claim 15, wherein the opening further has at least two sliding holes located at two sides of the opening respectively, and each of the first connecting portion and the second connecting portion has a sliding pillar disposed in the sliding hole for the flapper to slide along the sliding holes.

17. The heat dissipation system of claim 16, wherein the sliding hole has a curved shape.

18. The heat dissipation system of claim 11, further comprising a plurality of blockers disposed at two sides of the opening for blocking the flapper from being opened toward the interior of the case.

19. The heat dissipation system of claim 11, wherein any two adjacent flappers have an interval substantially equal to the width of the flapper.

20. The heat dissipation system of claim 11, wherein any two adjacent flappers have an interval substantially smaller than the width of the flapper so that the flappers are partially stacked on each other.
